(19) United States
(12) Patent Application Publication
(10) Pub. No.: US 2010/0101646 A1
(43) Pub. Date: Apr. 29, 2010

(54) NON-AUTOCLAVE LAMINATION PROCESS FOR MANUFACTURING SOLAR CELL MODULES

(75) Inventors: ROBERT J. CADWALLADER, Angier, NC (US); REBECCA L. SMITH, Vienna, WV (US); RICHARD ALLEN HAYES, Beaumont, TX (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/582,985

(22) Filed: Oct. 21, 2009

Related U.S. Application Data
(60) Provisional application No. 61/108,141, filed on Oct. 24, 2008.

(51) Int. Cl. H01L 31/00; B29C 65/14

(52) U.S. Cl. 136/259; 156/273.7

(57) ABSTRACT

Disclosed is an improved non-autoclave lamination process for manufacturing solar cell modules, which comprises an additional heating step following and in addition to a heat/vacuum process.

### CROSS-REFERENCE TO RELATED APPLICATION

This application claims priority to U.S. Provisional Application No. 61/108,141, filed on Oct. 24, 2008, which is incorporated herein by reference in its entirety.

### FIELD OF THE INVENTION

The invention relates to an improved non-autoclave lamination process useful for manufacturing solar cell modules.

### BACKGROUND OF THE INVENTION

Because they provide a sustainable energy resource, the use of solar cells is rapidly expanding. Solar cells are typically categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of self-supporting wafers (or cells) that are soldered together. The wafers generally have a thickness of between about 180 and about 240 μm. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for up to 25 to 30 years. In general, a solar cell module derived from wafer-based solar cell(s) comprises, in order of position from the front sun-facing side to the back non-sun-facing side: (1) an incident layer, (2) a front encapsulant layer, (3) a solar cell layer, (4) a back encapsulant layer, and (5) a backing layer.

The increasingly important alternative thin film solar cells are commonly formed from materials that include amorphous silicon (a-Si), microcrystalline silicon (μc-Si), cadmium telluride (CdTe), copper indium selenide (CuInSe₂ or CIS), copper indium/gallium diselenide (CuInGa₍₁₋ₓ₎Se₂ or CIGS), light absorbing dyes, and organic semiconductors. By way of example, thin film solar cells are disclosed in e.g., U.S. Pat. Nos. 5,507,881; 5,512,107; 5,948,176; 5,994,163; 6,040,521; 6,137,048; and 6,258,620 and U.S. Patent Publication Nos. 2007/0298590; 2007/0281090; 2007/0240759; 2007/0232057; 2007/0238285; 2007/0227578; 2007/0209699; and 2007/0079866. Thin film solar cells with a typical thickness of less than 2 μm are produced by depositing the semiconductor layers onto a superstrate or substrate formed of glass or a flexible film. During manufacture, it is common to include a laser scribing sequence that enables the adjacent cells to be directly interconnected in series, with no need for further solder connections between cells. As with wafer cells, the solar cell layer may further comprise electrical wirings such as cross ribbons and bus bars. Similarly, the thin film solar cells are further laminated to other encapsulant and protective layers to produce a weather resistant and environmentally robust module. Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a solar cell module derived from thin film solar cells may have one of two types of construction. The first type includes, in order of position from the front sun-facing side to the back non-sun-facing side, (1) a solar cell layer comprising a superstrate and a layer of thin film solar cell(s) deposited thereon at the non-sun-facing side, (2) a (back) encapsulant layer, and (3) a backing layer. The second type may include, in order of position from the front sun-facing side to the back non-sun-facing side, (1) an incident layer, (2) a (front) encapsulant layer, (3) a solar cell layer comprising a layer of thin film solar cell(s) deposited on a substrate at the sun-facing side thereof.

In addition, based on the material used in the incident layer and/or the backing layer, the solar cell modules can also be grouped into glass/glass type, glass/plastic type, plastic/plastic type, etc. In particular, a glass/glass type solar cell module refers to a type wherein both of the two outer most surface layers are formed of glass. For example, a glass/glass type solar cell module derived from wafer-based solar cells would comprise a solar cell layer sandwiched and encapsulated between two encapsulant layers, which are further sandwiched between a glass incident layer on the front sun-facing side and a glass backing layer on the back non-sun-facing side. On the other hand, a glass/glass type thin film solar cell module would have the semiconductor layers deposited on a glass substrate (or superstrate) and further laminated to an encapsulant layer and further to a glass incident (or backing) layer.

Various types of processes have been developed for manufacturing solar cell modules. One particular type of lamination process, which does not involve the use of autoclaves and is often referred to as “non-autoclave lamination process”, has been the subject of great interest in the past. Such a non-autoclave lamination process typically includes the steps of positioning all the component layers of the laminated structure to form a pre-lamination assembly and subjecting the assembly to heat, vacuum, and optionally pressure. See e.g., U.S. Pat. Nos. 3,234,062; 4,421,589; 5,238,519; 5,536,347; 5,759,698; 5,593,532; 5,993,582; 6,007,650; 6,134,784; 6,149,757; 6,241,839; 6,367,530; 6,369,316; 6,481,482; U.S. Patent Publication Nos. 2004/0182493; 2007/0215287, and PCT Patent Publication No. WO 2006/057771. Various types of laminators, such as the Meier ICOLAM® 10/08 laminator (Meier Vakuumtechnik GmbH, Bocholt, Germany), SPI-Laminators with model numbers 1834N, 1734N, 680N, 580 N, 580, and 480 (Spire Corporation, Bedford, Mass.), Module Laminators LM, LM-A and LM-SA series (NPC Incorporated, Tokyo, Japan), have been developed to perform the non-autoclave, or heat/vacuum lamination process. In particular, U.S. Pat. Nos. 5,593,532 and 6,369,316 disclose an improved non-autoclave lamination process wherein after undergoing the lamination process in a vacuum laminator, the module-stack (i.e., the pre-lamination assembly) is moved into a hardening oven to further harden the plastic sealing (i.e., encapsulant) layers. It is stated that such a process is useful when the encapsulant layers are formed of thermoset resins (e.g., poly(ethylene vinyl acetate) (EVA)) that require curing.

Certain acid copolymers of α-olefins and α,β-ethylenically unsaturated carboxylic acids and their ionic, neutralized derivatives (i.e., ionomers) are being utilized with greater frequency as encapsulant materials in solar cell modules due to their optical and safety properties. In addition, because acid copolymers and ionomers are thermoplastic polymers, when they are used in manufacture of solar cell modules, extra hardening or curing is not required, therefore simplifying the lamination process. See e.g., U.S. Pat. Nos. 3,957,537; 5,476,553; 5,478,402; 5,733,382; 5,762,720; 5,986,203; 6,114,046; 6,187,448; 6,320,116; 6,414,236; 6,586,271; 6,660,930; 6,693,237, U.S. Patent Publication Nos. 2003/0000568 and 2005/0279401, and Japanese Patent Nos. 2000-186114; 2001-089616; 2001-119047; 2001-119056; 2001-119057; 2001-144313; 2001-261904; 2004-031445; 2004-058583; 2006-032308; 2006-036875; and 2006-190867.

However, most of the commercially available laminators have only one heat source (e.g., a heated platen) positioned on one side (e.g., the bottom side) of the laminator chamber and consequently the assembly within the laminator chamber is heated from only one side. Due to the thickness of the glass sheets used in the glass/glass type of solar cell module, in order to allow sufficient heat to transfer to the other side of the assembly and therefore achieve sufficient bonding between the encapsulant layer and the adjacent glass sheet, it is often necessary to heat the assembly for an extended period of time. In modules wherein acid copolymers or ionomers are utilized in encapsulant layers this time period is generally about 40 to 60 minutes long. Such a lengthy period is undesirable because it can slow down production speed on an assembly line. There is a need to develop a more efficient lamination process for manufacturing glass/glass type solar cell modules that incorporate acid copolymers or ionomers as encapsulant material.

### SUMMARY OF THE INVENTION

Disclosed herein is a process for preparing a solar cell module comprising: (A) subjecting a pre-lamination assembly to a vacuum force of about 1 to about 100 torr within a closed chamber, wherein one side of the assembly is exposed to a first heat source, the pre-lamination assembly is optionally heated to a temperature of about 25° C. or higher, and the pre-lamination assembly is maintained at said vacuum force and optional temperature condition for about 1 to about 15 minutes, and wherein the pre-lamination assembly comprises (i) a solar cell layer comprising one or a plurality of electrically interconnected solar cells, the pre-lamination assembly having a front sun-facing side and a back non-sun-facing side, (ii) at least one thermoplastic sheet that is positioned to one side of the solar cell layer and comprises a thermoplastic polymer selected from the group consisting of acid copolymers, ionomers of acid copolymers, combinations of two or more acid copolymers, combinations of two or more ionomers of acid copolymers, and mixtures of one or more acid copolymers and one or more ionomers of acid copolymers and (iii) at least one glass sheet that is positioned adjacent to the at least one thermoplastic sheet; (B) increasing the temperature of the first heat source to heat the pre-lamination assembly to about 50° C. to about 150° C. while applying a pressure of about 1 atm to a surface of the pre-lamination assembly within the closed chamber, and maintaining the pre-lamination assembly at said vacuum, temperature, and pressure conditions for about 1 to about 15 minutes; (C) releasing the vacuum force within the chamber and exposing the pre-lamination assembly to ambient pressure; and (D) further exposing one or both sides of the pre-lamination assembly to a second heat source which heats the pre-lamination assembly to a temperature of about 70° C. to about 150° C. for about 1 minute to about 24 hours to form a solar cell module.

In one embodiment, steps (A)-(C) of the process are conducted within a vacuum laminator chamber wherein the first heat source is a heated platen positioned at one side of the vacuum laminator; and wherein the second heat source used in step (D) is selected from the group consisting of forced air ovens, convection ovens, radiant heat sources, infrared light, microwave ovens, hot air, and combinations of two or more thereof.

In a further embodiment, step (D) of the process is conducted using a conveyor belt with the second heat source being one or more infrared lamps.

In a yet further embodiment, the thermoplastic polymer comprised in the thermoplastic sheet is an ionomer that is an ionic, neutralized derivative of a precursor α-olefin carboxylic acid copolymer, and wherein about 10% to about 60% of the total content of the carboxylic acid groups present in the precursor α-olefin carboxylic acid copolymer have been neutralized with metal ions, and wherein the precursor α-olefin carboxylic acid copolymer comprises (i) copolymerized units of an α-olefin having 2 to 10 carbons and (ii) about 18 to about 30 wt %, based on the total weight of the α-olefin carboxylic acid copolymer, of copolymerized units of an α,β-ethylenically unsaturated carboxylic acid having 3 to 8 carbons.

In a yet further embodiment, the thermoplastic polymer comprised in the thermoplastic sheet is an acid copolymer that comprises (i) copolymerized units of an α-olefin having 2 to 10 carbons and (ii) about 18 to about 30 wt %, based on the total weight of the α-olefin carboxylic acid copolymer, of copolymerized units of an α,β-ethylenically unsaturated carboxylic acid having 3 to 8 carbons.

In a yet further embodiment, the at least one thermoplastic sheet comprised in the pre-lamination assembly is a front encapsulant sheet layer positioned to the front sun-facing side of the solar cell layer and the at least one glass sheet comprised in the pre-lamination assembly is an incident layer positioned adjacent to the at least one thermoplastic encapuslant sheet layer and on the side of the encapuslant sheet layer opposite from the solar cell layer.

In a yet further embodiment, the solar cells comprised in the pre-lamination assembly are wafer-based solar cells selected from the group consisting of crystalline silicon (c-Si) and multi-crystalline silicone (mc-Si) based solar cells and the pre-lamination assembly consists essentially of, in order of position, (i) an incident layer formed of the at least one glass sheet, (ii) a front encapsulant layer formed of the at least one thermoplastic sheet, (iii) the solar cell layer, (iv) a back encapsulant layer formed of a second thermoplastic sheet, and (v) a backing layer formed of a second glass sheet.

In a yet further embodiment, the solar cells comprised in the pre-lamination assembly are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductor based solar cells.

In a yet further embodiment, during steps (A)-(C) of the process, the pre-lamination assembly is positioned in the laminator chamber in such a way that the substrate side of the pre-lamination assembly is exposed to a heated platen; and during step (D), the pre-lamination assembly is positioned on the conveyor belt in such a way that the incident layer side of the pre-lamination assembly is exposed to the one or more infrared lamps.

In a yet further embodiment, during steps (A)-(C) of the process, the pre-lamination assembly is positioned in the laminator chamber in such a way that the superstrate side of the pre-lamination assembly is exposed to a heated platen; and during step (D), the pre-lamination assembly is positioned on the conveyor belt in such a way that the backing layer side of the pre-lamination assembly is exposed to the one or more infrared lamps.

Also disclosed herein is a solar cell module manufactured by the process described above.

### BRIEF DESCRIPTION OF THE DRAWINGS

FIG. 1 is a cross-sectional view, not-to-scale, of a glass/glass type wafer-based solar cell module prepared by a process disclosed herein.

FIG. 2 is a cross-sectional view, not-to-scale, of one particular glass/glass type thin film solar cell module prepared by a process disclosed herein.

FIG. 3 is a cross-sectional view, not-to-scale, of another glass/glass type thin film solar cell module prepared by a process disclosed herein.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein. Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce those polymers or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers.

The term “acid copolymer” as used herein refers to a polymer comprising copolymerized units of an α-olefin, an α,β-ethylenically unsaturated carboxylic acid, and optionally other suitable comonomer(s) such as an α,β-ethylenically unsaturated carboxylic acid ester.

The term “ionomer” as used herein refers to a polymer that comprises ionic groups that are metal ion carboxylates, for example, alkali metal carboxylates, alkaline earth carboxylates, transition metal carboxylates and/or mixtures of such carboxylates. Such polymers are generally produced by partially or fully neutralizing the carboxylic acid groups of a precursor or “parent” polymer that is an acid copolymer, as defined herein, for example by reaction with a base. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

Disclosed herein is an improved non-autoclave lamination process for manufacturing solar cell modules having at least one glass layer, including in particular glass/glass solar cell modules, wherein the module comprises at least one thermoplastic encapsulant sheet layer, the sheet comprising a thermoplastic polymer composition that comprises an acid copolymer, an ionomer of an acid copolymer, or a mixture of two or more thereof. That is, the thermoplastic polymer composition may additionally be a mixture of two or more acid copolymers, two or more ionomers of acid copolymers or it may also be a mixture of one or more acid copolymers with one or more ionomers of acid copolymers. Acid copolymers useful as components of the thermoplastic polymer composition comprise copolymerized units of an α-olefin, an α,β-ethylenically unsaturated carboxylic acid, and optionally other suitable comonomer(s) such as an α,β-ethylenically unsaturated carboxylic acid ester. Ionomers useful as components of the thermoplastic polymer composition comprise ionic groups that are metal ion carboxylates, for example, alkali metal carboxylates, alkaline earth carboxylates, transition metal carboxylates and/or mixtures of such carboxylates. That is, the ionomers may comprise metal ion carboxylates that are mixtures of two or more alkali metal carboxylates, mixtures of two or more alkaline earth carboxylates, and mixtures of two or more transition metal carboxylates. The ionomers may also comprise mixtures of one or more members of these species, for example a mixture of alkali metal carboxylates and transition metal carboxylates. Such polymers are generally produced by partially or fully neutralizing the carboxylic acid groups of a precursor or “parent” polymer that is an acid copolymer, as defined herein, for example by reaction with a base or a mixture of bases. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

Use of the improved non-autoclave lamination process disclosed herein accelerates module production speed by permitting a reduction in the time period required for the heating step that is performed within the heated chamber of the laminator. This promotes efficiency in assembly line operations, which are common industry practices in the production of solar cell modules.

The improved non-autoclave lamination process may comprise at least four steps, a first step wherein a pre-lamination assembly is subjected to a vacuum force within a chamber, generally within a laminator having a heat source positioned on one side of the chamber; a second step wherein heat and pressure is applied to the pre-lamination assembly; a third step wherein the vacuum and pressure are released; and a fourth step wherein the thus-treated pre-lamination assembly is heated to a temperature of at least 70° C. at ambient pressure, to complete the lamination process. The process of the invention permits the first three steps to be conducted within a time frame that is considerably shorter than that which is usual in solar cell lamination procedures, particularly those wherein solar cell modules that contain acid copolymer and/or ionomer encapsulant layers are produced.

The lamination process will comprise at least the following steps: (1) subjecting a pre-lamination assembly comprising a multilayer structure comprising a solar cell layer, a thermoplastic encapsulant sheet layer and at least one glass sheet layer to a vacuum force of about 1 to about 100 torr, or about 1 to about 70 torr, or about 1 to about 50 torr, or about 2 to about 40 torr within a closed chamber, exposing a first side of the pre-lamination assembly to a first heat source, optionally heating the pre-lamination assembly to a temperature of about 25° C. or higher, or 25° to about 100° C., and maintaining the pre-lamination assembly under said vacuum and optional temperature conditions for about 1 to about 15 minutes, or about 5 to about 10 minutes; (2) increasing the temperature of the first heat source to heat the pre-lamination assembly to a temperature of about 50° C. to about 150° C., or about 50° C. to about 135° C., or about 70° C. to about 135° C. while applying a pressure of about 1 atmosphere to a surface of the pre-lamination assembly and maintaining the vacuum, temperature, and pressure conditions for about 1 to about 15 minutes, or about 5 to about 10 minutes; (3) releasing the vacuum force and pressure and exposing the pre-lamination assembly to ambient pressure; and (4) removing the thus-treated pre-lamination assembly from the chamber and further exposing one or more sides of the pre-lamination assembly to a second heat source which heats the assembly to a temperature of about 70° C. to about 150° C., or about 70° C. to about 135° C., or about 80° C. to about 135° C., or about 90° C. to about 135° C. for a period of about 1 minute to about 24 hours, or about 5 minutes to about 12 hours to obtain a laminated solar cell module.

In steps (1) through (3), the pre-lamination assembly may be contained within a vacuum laminator chamber of any suitable type of laminator (such as the Meier ICOLAM® 10/08 laminator (Meier Vakuumtechnik GmbH, Bocholt, Germany), SPI-Laminators with model numbers 1834N, 1734N, 680N, 580 N, 580, and 480 (Spire Corporation, Bedford, Mass.), Module Laminators LM, LM-A and LM-SA series (NPC Incorporated, Tokyo, Japan), in which a heat source is located at one side, generally the bottom side of the lamination chamber. More particularly, the laminator may have a heated platen (e.g., an electrically heated platen) positioned at one side, generally the bottom side, of the lamination chamber, and therefore the pre-lamination assembly will be heated by conductive heating from its bottom side. Additionally, pressure may be applied to the pre-lamination assembly by an inflated bladder positioned on the top of the assembly during step (2).

Any of a variety of heat sources may be used as the second heat source in step (4) of the process. For example, the heat source may be an oven (e.g., forced air oven or convection oven) or a radiant heat source, infrared light (e.g., infrared light supplied by infrared lamps such as mid-wave infrared lamps), hot air, microwave, or combinations of two or more thereof. During step (4), heat may be supplied to the pre-lamination assembly by heat sources positioned on one or more sides of the pre-lamination assembly. In one particular embodiment, step (4) of the process may be conducted while the assembly is transported on a conveyor belt with the assembly being heated from two sides (i.e., the top and bottom sides). In a further embodiment, the pre-lamination assembly is placed on a conveyor belt and heated only from one side, generally the side that is not in contact with the conveyor belt, by infrared lamps. In general, the time that is needed to complete step (4) depends on the particular heating temperature to which the pre-lamination assembly is exposed. In a further embodiment, as an additional step prior to step (4), the pre-lamination assembly may be cooled following completion of step (3) but prior to being exposed to the second heat source in step (4). In a yet further embodiment, the process disclosed herein is a continuous process wherein the assembly is directly conducted to step (4) after the vacuum and pressure in the chamber have been released in step (3).

Further disclosed herein is a solar cell module that is manufactured by the improved non-autoclave lamination process, wherein the solar module comprises (a) a solar cell layer comprising one or a plurality of solar cells, (b) at least one thermoplastic sheet formed of a thermoplastic polymer composition comprising an acid copolymer, an ionomer of an acid copolymer, or a mixture thereof (i.e. a combination of two or more acid copolymers, a combination of two or more ionomers of acid copolymers, or a combination of at least one acid copolymer with one or more ionomers of acid copolymers), which sheet is positioned to one side of the solar cell layer, and (c) at least one glass sheet positioned such that the at least one thermoplastic sheet is between the solar cell layer and the at least one glass sheet.

The acid copolymers useful as components of the thermoplastic polymer composition are copolymers of α-olefins having 2 to 10 carbons and α,β-ethylenically unsaturated carboxylic acids having 3 to 8 carbons. In one embodiment, the acid copolymer comprises about 18 to about 30 wt %, or 18 to about 25 wt %, or 20 to about 25 wt %, or about 21 to about 24 wt % of copolymerized units of the α,β-ethylenically unsaturated carboxylic acid, based on the total weight of the copolymer.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and combinations of two or more of such comonomers. In one embodiment, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and combinations of two or more thereof. In one embodiment, the α,β-ethylenically unsaturated carboxylic acid is selected from acrylic acids, methacrylic acids, and combinations of two or more thereof.

The acid copolymers may further comprise copolymerized units of other comonomer(s), such as unsaturated carboxylic acids having 2 to 10, or preferably 3 to 8 carbons, or derivatives thereof. Suitable acid derivatives include acid anhydrides, amides, and esters. In one embodiment, the acid derivatives used are esters. Specific examples of suitable esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, dimethyl maleates, diethyl maleates, dibutyl maleates, dimethyl fumarates, diethyl fumarates, dibutyl fumarates, vinyl acetates, vinyl propionates, and mixtures of two or more thereof. Also included are glycidyl methacrylates, vinyl acetates, and combinations of two or more thereof. In certain embodiments, the acid copolymers may be dipolymers composed of only an α-olefin and an α,β-ethylenically unsaturated carboxylic acid.

The acid copolymers may be polymerized as disclosed in U.S. Pat. Nos. 3,404,134; 5,028,674; 6,500,888; and 6,518,365.

Suitable acid copolymers may have a melt flow rate (MFR) of about 0.5 to about 1000 g/10 min, or about 0.5 to about 500 g/10 min, or about 1 to about 100 g/10 min, or about 1 to about 20 g/10 min, or about 1.5 to about 10 g/10 min, as determined in accordance to ASTM D1238 at 190° C. and 2.16 kg.

The ionomers useful as components of the thermoplastic polymer composition are ionic, neutralized derivatives of precursor acid copolymers, such as those acid copolymers disclosed above. In one embodiment, the ionomers are produced by neutralizing the acid groups of the precursor acid copolymers with a reactant that is a source of metal ions in an amount such that neutralization of about 10% to about 60%, or about 20% to about 55%, or about 35% to about 50% of the carboxylic acid groups takes place, based on the total carboxylic acid content of the precursor acid copolymers as calculated or measured for the non-neutralized precursor acid copolymers. Neutralization may often be accomplished by reaction of the precursor acid polymer with a base, such as sodium hydroxide, potassium hydroxide, or zinc hydroxide.

The metal ions may be monovalent ions, divalent ions, trivalent ions, multivalent ions, or mixtures thereof. Useful monovalent metallic ions include, but are not limited to sodium, potassium, lithium, silver, mercury, and copper. Useful divalent metallic ions include, but are not limited to beryllium, magnesium, calcium, strontium, barium, copper, cadmium, mercury, tin, lead, iron, cobalt, nickel, and zinc. Useful trivalent metallic ions include, but are not limited to, aluminum, scandium, iron, and yttrium. Useful multivalent metallic ions include, but are not limited, to titanium, zirconium, hafnium, vanadium, tantalum, tungsten, chromium, cerium, and iron. It is noted that when the metallic ion is multivalent, complexing agents such as stearate, oleate, salicylate, and phenolate radicals may be included, as disclosed in U.S. Pat. No. 3,404,134. In one embodiment, the metal ions are monovalent or divalent metal ions. In a further embodiment, the metal ions are selected from sodium, lithium, magnesium, zinc, potassium and mixtures thereof. In a yet further embodiment, the metal ions are selected from sodium, zinc, and mixtures thereof. In a yet further embodiment, the metal ion is sodium.

The precursor acid copolymers may be neutralized as disclosed in U.S. Pat. No. 3,404,134.

The ionomers that are useful as components of the thermoplastic polymer composition may have a MFR of about 0.75 to about 19 g/10 min, or about 1 to about 10 g/10 min, or about 1.5 to about 5 g/10 min, or about 2 to about 4 g/10 min, as determined in accordance with ASTM D1238 at 190° C. and 2.16 kg and the precursor acid copolymers, from which the ionomers are derived may have a MFR about 0.5 to about 1000 g/10 min, or about 0.5 to about 500 g/10 min, or about 1 to about 100 g/10 min, or about 1 to about 20 g/10 min, or about 1.5 to about 10 g/10 min, as determined in accordance to ASTM D1238 at 190° C. and 2.16 kg.

The thermoplastic polymer composition may further contain one or more additives, such as processing aids, flow enhancing additives, lubricants, pigments, dyes, flame retardants, impact modifiers, nucleating agents, anti-blocking agents such as silica, thermal stabilizers, UV absorbers, UV stabilizers, hindered amine light stabilizers (HALS), silane coupling agents, dispersants, surfactants, chelating agents, coupling agents, reinforcement additives (e.g., glass fiber), and fillers.

The thermoplastic sheet may be in single layer or multilayer form. By “single layer”, it is meant that the sheet is made of or consists essentially of the thermoplastic polymer composition comprising acid copolymers, ionomers of acid copolymers, or combinations of two or more thereof. When in a multilayer form, at least one surface sub-layer of the multilayer sheet is made of or consists essentially of the thermoplastic polymer composition comprising acid copolymers, ionomers of acid copolymers, or combinations of two or more thereof, while the other sub-layer(s) may be made of any other suitable polymeric material(s), such as poly(ethylene vinyl acetates), poly(vinyl acetals) (including acoustic grade poly(vinyl acetals)), polyurethanes, polyvinylchlorides, polyethylenes (e.g., linear low density polyethylenes), polyolefin block copolymer elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, or combinations of two or more thereof.

The total thickness of the thermoplastic sheet may be in the range of about 10 to about 591 mils (about 0.25 to about 15 mm), or about 10 to about 240 mils (about 0.25 to about 6.1 mm), or about 15 to about 90 mils (about 0.38 to about 2.3 mm), or about 20 to about 60 mils (about 0.51 to about 1.5 mm), or about 25 to about 45 mils (about 0.64 to about 1.1 mm), or about 25 to about 35 mils (about 0.64 to about 0.89 mm).

The thermoplastic sheet may have a smooth or rough surface on one or both sides before it is laminated to the other component layers of the solar cell module. In one embodiment, the sheet has rough surfaces on both sides to facilitate deaeration during the lamination process.

The thermoplastic sheet may be produced by any suitable process. For example, the sheets may be formed through dipcoating, solution casting, compression molding, injection molding, lamination, melt extrusion, blown film, extrusion coating, tandem extrusion coating, or by any other procedures that are known to those of skill in the art. In one embodiment, the sheets are formed by melt extrusion, melt coextrusion, melt extrusion coating, or tandem melt extrusion coating processes.

The term “solar cell” is meant to include any article which can convert light into electrical energy. Solar cells useful in the invention include, but are not limited to, wafer-based solar cells (e.g., c-Si or mc-Si based solar cells, as described above in the background section) and thin film solar cells (e.g., a-Si, μc-Si, CdTe, CIS, CIGS, light absorbing dyes, or organic semiconductor based solar cells, as described above in the background section). Within the solar cell layer, the solar cells may be electrically interconnected and/or arranged in a flat plane. In addition, the solar cell layer may further comprise electrical wirings, such as cross ribbons and bus bars. When in use, the solar cell layer has a “front sun-facing side” that faces the light source and a “back non-sun-facing side” that faces away from the light source. Therefore, when a solar cell module is assembled, the module or the pre-lamination assembly as a whole or any component layer thereof (i.e., the solar cell layer or the encapsulant layer) also has a “front sun-facing side” that, when in use, faces the light source and a “back non-sun-facing side” that, when in use, faces away from the light source. To allow efficient transmission of sunlight into the solar cells, the film or sheet layers positioned to the front sun-facing side of the solar cell layer are preferably made of transparent material.

The term “glass” includes not only window glass, plate glass, silicate glass, sheet glass, low iron glass, tempered glass, tempered CeO-free glass, and float glass, but also colored glass, specialty glass (such as those types of glass containing ingredients to control solar heating), coated glass (such as those sputtered with metals (e.g., silver or indium tin oxide) for solar control purposes), low E-glass, Toroglas® glass (Saint-Gobain N.A. Inc., Trumbauersville, Pa.), Solexia™ glass (PPG Industries, Pittsburgh, Pa.) and Starphire® glass (PPG Industries). Such specialty glasses are disclosed in, e.g., U.S. Pat. Nos. 4,615,989; 5,173,212; 5,264,286; 6,150,028; 6,340,646; 6,461,736; and 6,468,934. It is understood, however, that the type of glass to be selected depends on the intended use.

The solar cell module manufactured by the improved non-autoclave lamination process is typically comprised of at least one of the thermoplastic sheets laminated to one side of the solar cell layer and at least one glass sheet further laminated to the thermoplastic sheet. By “laminated”, it is meant that, within a laminated structure, the two layers are bonded either directly (i.e., without any additional material between the two layers) or indirectly (i.e., with additional material, such as interlayer or adhesive materials, between the two layers). In one particular embodiment, the thermoplastic sheet is directly laminated to one side of the solar cell layer while the at least one glass sheet is further laminated to the thermoplastic sheet.

The solar cell module may further comprise additional encapsulant layers comprising other polymeric materials, such as poly(ethylene vinyl acetates), poly(vinyl acetals) (including acoustic grade poly(vinyl acetals)), polyurethanes, poly(vinyl chlorides), polyethylenes (e.g., linear low density polyethylenes), polyolefin block elastomers, copolymers of α-olefins and α,β-ethylenically unsaturated carboxylic acid esters) (e.g., ethylene methyl acrylate copolymers and ethylene butyl acrylate copolymers), silicone elastomers, epoxy resins, and combinations of two or more thereof. Such additional encapsulant layers may have a thickness of about 1 to about 120 mils (0.026 to about 3 mm), or about 10 to about 90 mils (about 0.25 to about 2.3 mm), or about 15 to about 60 mils (about 0.38 to about 1.5 mm), or about 20 to about 45 mils (0.51 to about 1.1 mm).

The solar cell module may further comprise other functional film or sheet layers (e.g., dielectric layers or barrier layers) embedded within the module. Such functional layers may be derived from any of the above mentioned polymeric films or those that are coated with additional functional coatings. For example, poly(ethylene terephthalate) films coated with a metal oxide coating, such as those disclosed within U.S. Pat. Nos. 6,521,825 and 6,818,819 and European Patent No. EP1182710, may function as oxygen and moisture barrier layers in the laminates.

If desired, a layer of nonwoven glass fiber (scrim) may also be included between the solar cell layers and the encapsulants to facilitate deaeration during the lamination process or to serve as reinforcement for the encapsulants. The use of such scrim layers is disclosed within, e.g., U.S. Pat. Nos. 5,583,057; 6,075,202; 6,204,443; 6,320,115; and 6,323,416 and European Patent No. 0769818.

If desired, one or both surfaces of any of the component layers of the solar cell module may be treated prior to the lamination process to enhance the adhesion to other laminate layers. This adhesion enhancing treatment may take any form known within the art and includes flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 discloses a film or sheet with improved bondability, which has a thin layer of carbon deposited on one or both surfaces. Other exemplary adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and have a thickness of about 0.0004 to about 1 mil (about 0.00001 to about 0.03 mm), or preferably, about 0.004 to about 0.5 mil (about 0.0001 to about 0.015 mm), or more preferably, about 0.004 to about 0.1 mil (about 0.0001 to about 0.003 mm).

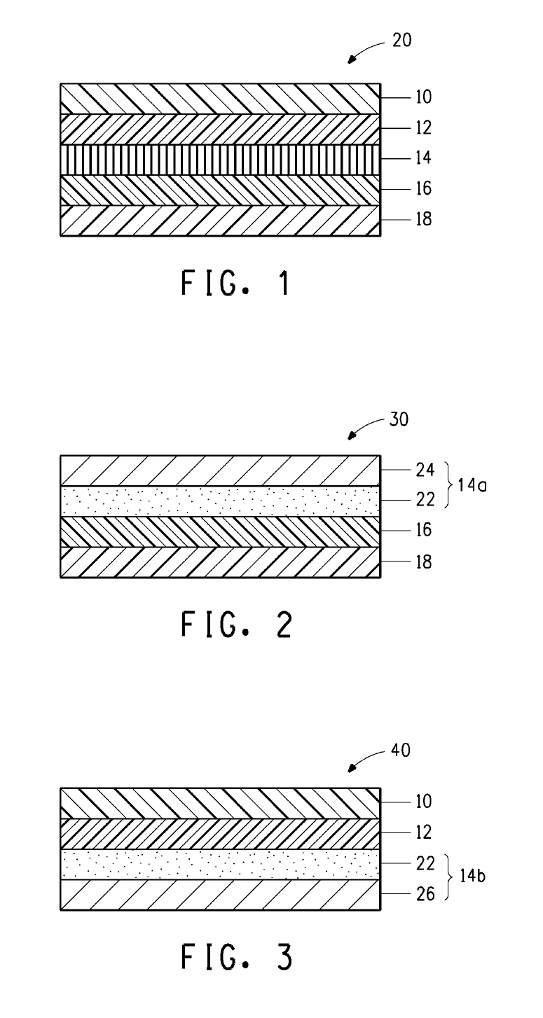

In one particular embodiment (now referring to FIG. 1), where the solar cells are derived from wafer-based self supporting solar cell units, the solar cell module (20) may comprise, in order of position from the front sun-facing side to the back non-sun-facing side, (a) a glass incident layer (10), (b) front encapsulant layer (12), (c) a solar cell layer (14) comprised of one or more electrically interconnected solar cells, (d) a back encapsulant layer (16), and (e) a glass backing layer (18), wherein at least one or both of the front and back encapsulant layers (12 and 16) are formed of thermoplastic sheets comprising an acid copolymer, an ionomer of an acid copolymer, or a combination of two or more thereof.

In a further embodiment (now referring to FIG. 2), where the solar cells are derived from thin film solar cells, the solar cell module (30) may comprise, in order of position from the front sun-facing side to the back non-sun-facing side, (a) a solar cell layer (14a) comprising a glass superstrate (24) and a layer of thin film solar cell(s) (22) deposited thereon at the non-sun-facing side, (b) a (back) encapsulant layer (16) formed of the thermoplastic sheet disclosed above, and (c) a glass backing layer (18). In such an embodiment, during the lamination process, the pre-lamination assembly comprising all the component layers stacked in position may be placed within a laminator chamber in a way such that the superstrate side of the pre-lamination assembly would face the first heat source. For example, when the first heat source is a heated platen positioned at the bottom of the vacuum chamber of a laminator, the pre-lamination assembly may be positioned within the vacuum chamber with the superstrate side of the pre-lamination assembly at the bottom of the chamber. In a further embodiment, during step (4) the assembly may be positioned in a way such that only the backing layer side of the pre-lamination assembly would face the second heat source. For example, when the second heat source is one or more infrared lamps positioned above a conveyor belt, the pre-lamination assembly may be placed on the conveyor belt with the superstrate side on the conveyer belt surface and the glass backing layer facing the one or more infrared lamps.

In a yet further embodiment (now referring to FIG. 3), wherein the solar cells also incorporate thin film solar cells, the solar cell module (40) may comprise, in order of position from the front sun-facing side to the back non-sun-facing side, (a) a glass incident layer (10), (b) a (front) encapsulant layer (12) formed of the thermoplastic sheet disclosed above, and (c) a solar cell layer (14b) comprising a layer of thin film solar cell(s) (22) deposited on a glass substrate (26) at the sun-facing side thereof. In such an embodiment, during the lamination process, the pre-lamination assembly comprising all the component layers stacked in position may be positioned in such a way that the glass substrate side of the assembly would face the first heat source. For example, when the first heat source is a heated platen positioned at the bottom of the vacuum chamber of a laminator, the pre-lamination assembly may be positioned in the vacuum chamber with the glass substrate side of the assembly at the bottom. In a further embodiment, during step (4) the assembly may be positioned in such a way that only one side of the pre-lamination assembly would face the second heat source. For example, when the second heat source is one or more infrared lamps positioned above a conveyor belt, the pre-lamination assembly may be positioned on the conveyor belt with the glass substrate side in contact with the surface of the conveyer belt and the glass incident layer facing the one or more infrared lamps.

Yet further disclosed herein is a solar cell array comprising a series of the solar cell modules manufactured by the above described improved non-autoclave lamination process.

### EXAMPLES

### Examples E1-E8

The ionomer sheet used in each of the following examples was a 60 mil (1.78 mm) thick embossed ionomer sheet made of an ionomer of a copolymer of ethylene and methacrylic acid containing 21.7 wt % of copolymerized units of methacrylic acid, 26% neutralized with sodium ions, and having a MFR of 1.8 g/10 min (as determined in accordance with ASTM D1238 at 190° C. at 2.16 kg). The MFR of the precursor ethylene methacrylic acid copolymer, prior to neutralization, was 23 g/10 min (as determined in accordance with ASTM D1238 at 190° C. at 2.16 kg). In each of the examples, glass laminates (12×12 in (305×305 mm)) with the ionomer sheet sandwiched between two 2 mm thick annealed glass sheets were prepared as follows. The ionomer sheet was positioned between the two glass sheets to form a pre-lamination assembly which was then placed into an NPC vacuum press laminator (NPC Incorporated, Tokyo, Japan). The pneumatically raised pins on which the pre-lamination assembly sat were at a level of about 3 to about 5 mm above the electrically heated bottom plate that was held at the temperature noted in Table 1. The laminator lid was closed and the laminating chamber was evacuated to achieve a full vacuum of 2-5 torr in about 6 seconds. Such vacuum was maintained for various times specified in Table 1, and thereafter, the glass pre-lamination assembly was lowered onto the heated bottom plate and a bladder in the top of the vacuum press laminator was pressurized to 1 atm and pressed onto the surface of the assembly for the press time noted in Table 1. Then the laminator was rapidly brought to atmospheric pressure and the resulting laminates were removed from the laminator. Some samples from each example assembly were then allowed to cool to room temperature while others were subjected to further heat treatment. Specifically, the heat treatment involved placing the laminate samples into a forced air oven in which the temperature was maintained at 110° C. for an hour, then 120° C. for an hour, then 130° C. for an hour, then 140° C. for an hour, then 150° C. for an hour. The thus-treated laminates were removed from the oven and allowed to cool to room temperature.

TABLE 1

| | Laminating Condition | | | |
|---|---|---|---|---|
| | Temperature | Vacuum Time | Press Time | Total Time |
| Example | (° C.) | (min.) | (min.) | (min.) |
| E1 | 140 | 5 | 5 | 10 |
| E2 | 140 | 10 | 5 | 15 |
| E3 | 140 | 10 | 10 | 20 |
| E4 | 140 | 15 | 5 | 20 |
| E5 | 150 | 5 | 5 | 10 |
| E6 | 150 | 10 | 0 | 10 |
| E7 | 150 | 10 | 5 | 15 |
| E8 | 150 | 10 | 10 | 20 |

The laminate samples with or without the above-described heat treatment were then subjected to pummel testing as follows. A 15×30 cm test piece was cut from each sample and cooled for 8 hours at −18° C. The test piece was held in a pummel testing machine at a 45 degree angle to a supporting table. A force was evenly applied over a 10×15 cm area of the test piece with a 450 g flathead hammer at a predetermined rate until the glass became pulverized. Once the glass was pulverized, the percentage of the surface area of the ionomer sheet that became unglued from the glass sheet was calculated and a pummel value was assigned as indicated in Table 2.

TABLE 2

| Percentage of the Ionomer Sheet Surface | |
|---|---|
| that Became Unglued From the Glass | Pummel Value |
| 100 | 0 |
| 90 | 1 |
| 80 | 2 |
| 70 | 3 |
| 60 | 4 |
| 50 | 5 |
| 40 | 6 |
| 30 | 7 |
| 20 | 8 |
| 10 | 9 |
| 0 | 10 |

The pummel tests were performed on both surfaces of the laminate samples and reported in Table 3. The “bottom” surface refers to the glass sheet that is closer to the heated platen when the sample was placed in the laminator and the “top” surface refers to the glass sheet that is opposite from the heated platen.

TABLE 3

| | Pummel Value | | | Pummel Value | | |
|---|---|---|---|---|---|---|
| | (no heat treatment) | | | (heat-treated) | | |
| Example | Top | Bottom | Average | Top | Bottom | Average |
| E1 | 1 | 3 | 2 | 8 | 8 | 8 |
| E2 | 0 | 0 | 0 | 8 | 8 | 8 |
| E3 | 2 | 6 | 4 | 8 | 8 | 8 |
| E4 | 0.5 | 1 | 0.75 | 8 | 8 | 8 |
| E5 | 1.5 | 0.5 | 1 | 8 | 8 | 8 |
| E6 | 0.5 | 0.5 | 0.5 | 8 | 8 | 8 |
| E7 | 0.5 | 5 | 2.75 | 8 | 8 | 8 |
| E8 | 2 | 4 | 3 | 8 | 8 | 8 |

### Examples E9-E14

A series of 12×12 in (305×305 mm) solar cell modules described below in Table 4 are prepared. For each solar cell module, layers 1 and 2 constitute the incident layer and the front encapsulant layer, respectively, and Layers 4 and 5 constitute the back encapsulant layer and the backing layer, respectively, where applicable.

The lamination processes used are as follows. The component layers of the modules are stacked to form a pre-lamination assembly. For the assembly containing a polymeric film layer as the outer surface layer (e.g., E12), a cover glass sheet is placed over the film layer. The pre-lamination assembly is then placed within a Meier ICOLAM® vacuum press laminator (Meier laminator; Meier Vakuumtechnik GmbH, Bocholt, Germany) with the first layer (i.e., Layer 1 for E9, E11, E12, and E14 or Layer 3 for E10 and E13) on the bottom adjacent to the heated platen, which is pre-heated to the temperature noted below in Table 5. The pre-lamination assemblies are placed on raised pneumatic pins (5 mm above heated platen) during the vacuum step and then are lowered onto the heated platen during the pressing step. The lamination cycle includes a vacuum step (vacuum of 3 in Hg (76 mm Hg)) for the time noted below in Table 5 and a pressing step wherein the bladder on the top surface of the laminator is inflated with 1 atm air for the time noted below in Table 5. Afterwards, the pre-lamination assemblies are removed from the laminator to undergo further heat treatment. Specifically, the assemblies from E9, E10, and E13 are placed under an array of midwave infrared lamps for 10 minutes with the infrared emissions only on the top layer (i.e., Layer 3 of E9 or Layer 5 for E10 and E13). E11 and E12 are placed in a convection oven at a temperature of 100° C. for 12 hours. E14 is placed in a forced air oven at a temperature of 150° C. for 0.5 hours. The resulting laminates are then allowed to cool to room temperature.

TABLE 6

| | Laminate Structure | | | | |
|---|---|---|---|---|---|
| Example | Layer 1 | Layer 2 | Layer 3 | Layer 4 | Layer 5 |
| E9 | | | Solar Cell-1 | ION-1 | Glass-1 |
| E10 | Glass-2 | ION-2 | Solar Cell-2 | | |
| E11 | | | Solar Cell-3 | ION-3 | Glass-1 |
| E12 | Glass-1 | ION-2 | Solar Cell-4 | ACR-1 | Glass-1 |
| E13 | | | Solar Cell-5 | ION-3 | Glass-2 |
| E14 | Glass-1 | ION-2 | Solar Cell-4 | ION-2 | Glass-2 |

Note:
ACR 1 is a 20 mil (0.51 mm) thick embossed sheet made of a copolymer of ethylene and methacrylic acid containing 18 wt % of polymerized residues of methacrylic acid and having melt flow rate (MFR) 2.5 g/10 min (as determined in accordance with ASTM D1238 at 190° C. and 2.16 kg);
ION-1 is a 60 mil (1.5 mm) thick embossed sheet made from an ionomer of a copolymer of ethylene and methacrylic acid containing 21.7 wt % of polymerized units of methacrylic acid, 26% neutralized with sodium ions, MFR 1.8 g/10 min (as determined in accordance with ASTM D1238 at 190° C. and 2.16 kg). The parent copolymer of ethylene and methacrylic acid has a MFR of 23 g/10 min prior to neutralization;
ION-2 is a 20 mil (0.51 mm) thick embossed sheet made from an ionomer of a copolymer of ethylene and methacrylic acid) containing 23.2 wt % of polymerized units of methacrylic acid, 43% neutralized with sodium ions, MFR of 3.2 g/10 min (190° C. and 2.16 kg). The precursor copolymer of ethylene and methacrylic acid has a MFR of 270 g/10 min prior to neutralization;
ION-3 is a 35 mil (0.89 mm) thick embossed sheet made from an ionomer of a copolymer of ethylene and methacrylic acid containing 21.7 wt % of polymerized units of methacrylic acid, 25% neutralized with zinc ions, MFR of 1.7 g/10 min (at 190° C. and 2.16 kg). The copolymer of ethylene and methacrylic acid has a MFR of 23 g/10 min prior to neutralization;
Solar Cell-1 is a 10 × 10 in (254 × 254 mm) a-Si based thin film solar cell with a glass superstrate (U.S. Pat. No. 6,353,042, column 6, line 36);
Solar Cell-2 is a 10 × 10 in (254 × 254 mm) CIS based thin film solar cell with a glass substrate (U.S. Pat. No. 6,353,042, column 6, line 19);
Solar Cell-3 is a 10 × 10 in (254 × 254 mm) CdTe based thin film solar cell with a glass superstrate (U.S. Pat. No. 6,353,042, column 6, line 49);
Solar Cell-4 is a silicon solar cell made from a 10 × 10 in (254 × 254 mm) polycrystalline EFG-grown wafer (U.S. Pat. No. 6,660,930, column 7, line 61);
Solar Cell-5 is a thin film solar cell deposited on a 12 × 12 in (305 × 305 mm) glass sheet (U.S. Pat. Nos. 5,512,107; 5,948,176; 5,994,163; 6,040,521; 6,137,048; and 6,258,620);
Glass-1 is Starphire ® glass from PPG Industries;
Glass-2 is a 2.5 mm thick clear annealed float glass sheet.

TABLE 5

| | Laminator Temperature | Vacuum Time | Press Time |
|---|---|---|---|
| Example | (° C.) | (min) | (min) |
| E9 | 140 | 10 | 10 |
| E10 | 145 | 5 | 10 |
| E11 | 150 | 5 | 10 |
| E12 | 140 | 5 | 5 |
| E13 | 145 | 10 | 10 |
| E14 | 150 | 10 | 10 |

What is claimed is:

1. A process for preparing a solar cell module comprising:
(A) subjecting a pre-lamination assembly to a vacuum force of about 1 to about 100 torr within a closed chamber, wherein one side of the assembly is exposed to a first heat source, the pre-lamination assembly optionally heated to a temperature of about 25° C. or higher, and the pre-lamination assembly is maintained at said vacuum force and optional temperature conditions for about 1 to about 15 minutes, and wherein the pre-lamination assembly comprises (i) a solar cell layer comprising one or a plurality of electrically interconnected solar cells, the pre-lamination assembly having a front sun-facing side and a back non-sun-facing side, (ii) at least one thermoplastic sheet that is positioned to one side of the solar cell layer and comprises a thermoplastic polymer selected from the group consisting of acid copolymers, ionomers of acid copolymers, and combinations of two or more thereof, and (iii) at least one glass sheet that is positioned adjacent to the at least one thermoplastic sheet;
(B) increasing the temperature of the first heat source to heat the pre-lamination assembly to about 50° C. to about 150° C. while applying a pressure of about 1 atm to a surface of the pre-lamination assembly within the closed chamber, and maintaining the pre-lamination assembly at said vacuum, temperature, and pressure conditions for about 1 to about 15 minutes;
(C) releasing the vacuum force within the chamber and exposing the pre-lamination assembly to ambient pressure; and
(D) further exposing one or more sides of the pre-lamination assembly to a second heat source which heats the pre-lamination assembly to a temperature of about 70° C. to about 150° C. for about 1 minute to about 24 hours to form the solar cell module.

2. The process of claim 1, wherein steps (A)-(C) are conducted within a vacuum laminator chamber with the first heat source being a heated platen positioned at one side of the vacuum laminator; and wherein the second heat source used in step (D) is selected from the group consisting of forced air ovens, convection ovens, radiant heat sources, infrared light, microwave ovens, hot air, and combinations of two or more thereof.

3. The process of claim 2, wherein step (D) is conducted using a conveyor belt with the second heat source being infrared light supplied by one or more infrared lamps.

4. The process of claim 1, wherein the thermoplastic polymer is an ionomer that is an ionic, neutralized derivative of a precursor α-olefin carboxylic acid copolymer, and wherein about 10% to about 60% of the total content of the carboxylic acid groups present in the precursor α-olefin carboxylic acid copolymer have been neutralized with metal ions, and wherein the precursor α-olefin carboxylic acid copolymer comprises (i) copolymerized units of an α-olefin having 2 to 10 carbons and (ii) about 18 to about 30 wt %, based on the total weight of the α-olefin carboxylic acid copolymer, of copolymerized units of an α,β-ethylenically unsaturated carboxylic acid having 3 to 8 carbons.

5. The process of claim 1, wherein the thermoplastic polymer is an acid copolymer that comprises (i) copolymerized units of an α-olefin having 2 to 10 carbons and (ii) about 18 to about 30 wt %, based on the total weight of the α-olefin carboxylic acid copolymer, of copolymerized units of an α,β-ethylenically unsaturated carboxylic acid having 3 to 8 carbons.

6. The process of claim 3, wherein the at least one thermoplastic sheet is a front encapsulant sheet layer positioned to the front sun-facing side of the solar cell layer and the at least one glass sheet is an incident layer positioned adjacent' to the at least one thermoplastic encapsulant sheet layer and opposite from the solar cell layer.

7. The process of claim 3, where the at least one thermoplastic sheet is a back encapsulant sheet layer positioned to the back non-sun-facing side of the solar cell layer and the at least one glass sheet is a backing layer positioned adjacent to the back encapsulant sheet layer and on the side of the encapsulant sheet layer opposite from the solar cell layer.

8. The process of claim 6, wherein the solar cells are wafer-based solar cells selected from the group consisting of crystalline silicon and multi-crystalline silicone based solar cells and wherein the pre-lamination assembly consists essentially of, in order of position, (i) an incident layer formed of the at least one glass sheet, (ii) a front encapsulant layer formed of the at least one thermoplastic sheet, (iii) the solar cell layer, (iv) a back encapsulant layer formed of a second thermoplastic sheet, and (v) a backing layer formed of a second glass sheet.

9. The process of claim 6, wherein the solar cells are thin film solar cells selected from the group consisting of amorphous silicon, microcrystalline silicon, cadmium telluride, copper indium selenide, copper indium/gallium diselenide, light absorbing dyes, and organic semiconductors based solar cells, and the solar cell layer further comprises a substrate as an outermost layer of the pre-lamination assembly at the back non-sun-facing side and upon which the thin film solar cells are deposited.

10. The process of claim 7, wherein the solar cells are thin film solar cells selected from the group consisting of amorphous silicon, microcrystalline silicon, cadmium telluride, copper indium selenide, copper indium/gallium diselenide, light absorbing dyes, and organic semiconductor based solar cells, and the solar cell layer further comprises a superstrate as an outermost layer of the pre-lamination assembly at the front sun-facing side and upon which the thin film solar cells are deposited.

11. The process of claim 9, wherein, during steps (A)-(C), the pre-lamination assembly is positioned in the laminator chamber in such a way that the substrate outermost layer side of the pre-lamination assembly is exposed to the heated platen; and during step (D), the pre-lamination assembly is positioned on the conveyor belt in such a way that the incident layer side of the pre-lamination assembly is exposed to the one or more infrared lamps.

12. The process of claim 10, wherein, during steps (A)-(C), the pre-lamination assembly is positioned in the laminator chamber in such a way that the superstrate side of the pre-lamination assembly is exposed to the heated platen; and during step (D), the pre-lamination assembly is positioned on the conveyor belt in such a way that the backing layer side of the pre-lamination assembly is exposed to the one or more infrared lamps.

13. A solar cell module manufactured by the process of claim 1.
